(19) United States
(12) Patent Application Publication
(10) Pub. No.: US 2004/0179628 A1
(43) Pub. Date: Sep. 16, 2004

(54) Method and apparatus for digital data transmission and reception using synthetically generated frequency

(76) Inventor: Abraham Haskin, Haifa (IL)

Correspondence Address: WILMER CUTLER PICKERING HALE AND DORR LLP, 300 PARK AVENUE, NEW YORK, NY, 10022, US

(21) Appl. No.: 10/475,029

(22) PCT Filed: Apr. 16, 2002
(86) PCT No.: PCT/IB02/03336

Related U.S. Application Data
(60) Provisional application No. 60/284,102, filed on Apr. 16, 2001.

(51) Int. Cl. H03K 7/06

(52) U.S. Cl. 375/271

(57) ABSTRACT

A frequency modulation method, system and computer readable-medium for enabling high speed, reliable and simple digital data modulation, transmission and reception. The system of the present invention includes a Synthetic Harmonic Waveform Generator for generating harmonic waves of the form cos(2πf_{dev}t) from a digital data bit stream. The system of the present invention uses the generated harmonic waves to create a frequency modulation signal of the form sin(2πf_{carrier}t±2πf_{dev}t), which is then transmitted. The present invention also includes a demodulation technique for receiving a signal of the form sin(2πf_{carrier}t±2πf_{dev}t), which is used to determine whether a “1” or “0” digital bit has been transmitted.

### FIELD OF THE INVENTION

The present invention relates to a method and apparatus for frequency modulation in general, and in particular to a method and apparatus utilizing frequency modulation for digital data transmission and reception.

### BACKGROUND OF THE INVENTION

A large variety of communication systems, such as TV and radio broadcast, analog cellular telephony, and remote sensing applications utilize a frequency modulation technique (FM). In most of these systems the transmitted signal is analog. The information in the FM signal is encoded by frequency deviations from the predefined central carrier frequency, the deviation being proportional to the amplitude of the analog information signal being transmitted. Conventionally, FM signals at the receiving site are demodulated, using analog processing techniques. These techniques generate an analog signal with an amplitude proportional to frequency deviation from the pre-defined central carrier frequency.

Recently, the sources of information to be transmitted using the FM modulation technique have become digital. The digital nature of the sources causes complications in frequency deviation generation when a regular analog technique is used, imposing certain limitations on the nature of digital data to be transmitted. At the same time, the demodulation, due to imperfection in frequency deviation generation, differences in local frequency sources and other effects caused by mobile transmitters/receivers becomes less reliable, yet being quite complicated.

There is a clear need for a method of frequency deviation generation enabling high speed, reliable and simple digital data modulation, transmission and reception using FM modulation.

### SUMMARY OF THE INVENTION

In accordance with the method and apparatus of the present invention, the modulation technique is performed by applying a digital data bit stream to the “Synthetic” Harmonic Waveform Generator (SHWG), which generates two harmonic waves of the form of cos(2πf_{dev}t). Further, the “synthetic” harmonic waveform generator is capable of introducing a relative phase shift of ±90° between the two waveforms as a function of the digital input bit stream. The two waveforms generated will be termed I-signal and Q-signal. Both the I and the Q signals are fed into the respective I and Q inputs of a quadrature modulator. A local RF oscillator provides an additional input to the quadrature modulator of a f_{carrier} frequency, producing the FM modulation signal of the shape sin(2π_{carrier}t±2πf_{dev}t). This signal is amplified and transmitted through a proper antenna.

The demodulation technique of the signal received is accomplished by applying down conversion from any desirable RF carrier frequency (f_{carrier}) based on a standard mixer device together with proper filtration techniques of a signal of the shape sin(2πf_{carrier}t±2πf_{dev}t). Application of the down converted signal to the quadrature demodulator input together with the local oscillator frequency of f_{IF}, produces at the I and Q outputs of the quadrature demodulator two harmonic signals of the shape cos(2πf_{dev}t) with a relative phase shift of ±90° between the two waveforms. Based on this phase shift, a decision is made whether a ‘1’ or ‘0’ bit has been transmitted.

### BRIEF DESCRIPTION OF THE DRAWINGS

The invention, it's preferred usage and further objects and advantages will be best understood by reference to the following detailed description of an illustrative embodiment when read in conjunction with the accompanying drawings, wherein:

FIG. 1 is a block diagram of an FM modulator constructed in accordance with the preferred embodiment of the present invention;

FIG. 2 is a block diagrams of one embodiment of the implementation of the “synthetic” harmonic wave generator,

FIG. 3 is a block diagrams of another embodiment of the implementation of the “synthetic” harmonic wave generator;

FIG. 4 is a block diagram of an FM receiver, including the FM demodulator, constructed in accordance with a preferred embodiment of the present invention; and

FIG. 5 is a flow chart of the phase evaluation-bit detection algorithm.

### DETAILED DESCRIPTION OF A PREFERRED EMBODIMENT

Transmitter

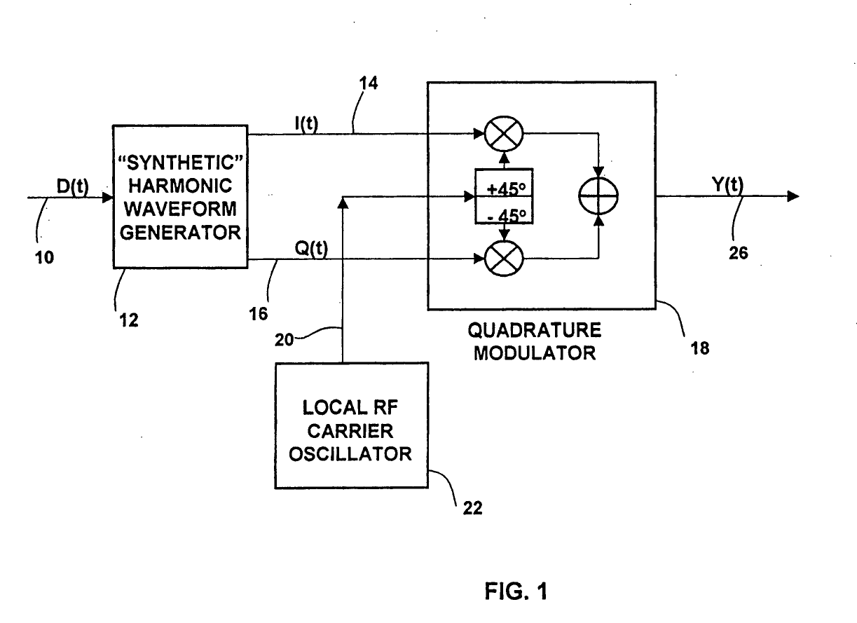

Attention is drawn now to FIG. 1, which is a block diagram of an FM modulator constructed in accordance with a preferred embodiment of the present invention. D(t), designated by numeral 10, is the digital data stream to be transmitted, where:

t=nT,

T is a one-bit time period; and

D(t)=is either ‘1‘or ’0’ for the entire T time period.

The D(t) signal is applied to the input of the “Synthetic” Harmonic Wave Generator 12, which generates two harmonic signals I(t), marked by numeral 14, and Q(t), marked by numeral 16, with the required FM deviation frequency f_{dev}where:

I(t)=cos(2πf_{dev}(t−(n−1)T)) for all {t: (n−1)T≦t<nT}, and all D(t).

Or:

I(t)=cos(2πf_{dev}T) for all {T=t−(n−1)T; for all t:(n−1)T≦t<nT}, and all D(t).

And where:

Q(t)=cos(2πf_{dev}(t−(n−1)T)+90°)=sin(2πf_{dev}(t−(n−1)T)) for all {(n−1)T≦t<nT}, and D(t)=‘1’;

And

Q(t)=cos(2πf_{dev}T(t−1)T)−90°)=−sin(2f_{dev}(t−(n−1)T)) for all {(n−1)T≦t<nT}, and D(t)=‘0’.

Or:

Q(t)=sin(2πf_{dev}T) for all {T=t−(n−1)T; for all t:(n−1)T≦t<nT}, and D(t)=‘1’;

And

Q(t)=−sin(2πf_{dev}T) for all {T=t−(n−1)T; for all t:(n−1)T≦t<nT}, and D(t)=‘0’.

When I(t) and Q(t) as defined above are applied to the quadrature modulator 18, who's function can be expressed mathematically as:

I(t)×sin(2πf_{carrier}t)+Q(t)×cos(2πf_{carrier}t)

together with the RF carrier frequency (f_{carrier}) 20 generated by the local RF carrier generator 22, a modulated FM signal Y(t) 26 is received at the output of the quadrature modulator. The output signal Y(t) is such that for:

$$D ( t ) = ‘ 1 ’ ; for all \{ t \text{:} ( n - 1 ) T \leq t < nT \} , \begin{matrix}Y ( t ) = I ( t ) \times sin ( 2 π {f}_{carrier} t ) + Q ( t ) \times cos ( 2 π {f}_{carrier} t ) \\ = cos ( 2 π {f}_{dev} T ) \times sin ( 2 π {f}_{carrier} t ) + sin ( 2 π {f}_{dev} T ) \times cos ( 2 π {f}_{carrier} t ) \\ = \frac{1}{2} sin ( 2 π {f}_{carrier} t + 2 π {f}_{dev} T ) + \frac{1}{2} sin ( 2 π {f}_{carrier} t - 2 π {f}_{dev} T ) + \\ \frac{1}{2} sin ( 2 π {f}_{dev} T + 2 π {f}_{carrier} t ) + \frac{1}{2} sin ( 2 π {f}_{dev} T - 2 π {f}_{carrier} t ) \\ = sin ( 2 π {f}_{carrier} t + 2 π {f}_{dev} T ) + \frac{1}{2} sin ( 2 π {f}_{carrier} t - 2 π {f}_{dev} T ) - \\ \frac{1}{2} sin ( 2 π {f}_{carrier} t - 2 π {f}_{dev} T ) \\ = sin ( 2 π {f}_{carrier} t + 2 π {f}_{dev} T ) \\ = sin ( 2 π {f}_{carrier} t + 2 π {f}_{dev} t - 2 π ( n - 1 ) {f}_{dev} T )\end{matrix}$$

The last term indicates a constant phase shift for an entire bit time period. The phase shift will be constant for any t, if f_{dev}T=integer. Thus, without imposing any limitation on the solution, it is possible to rewrite the above expression in a more general form for all D(t)=‘1’,

Y(t)=sin(2πf_{carrier}t+2πf_{dev}t)

In a similar manner, for:

$$D ( t ) = ‘ 0 ’ ; for all \{ t \text{:} ( n - 1 ) T \leq t < nT \} , \begin{matrix}Y ( t ) = I ( t ) \times sin ( 2 π {f}_{carrier} t ) + Q ( t ) \times cos ( 2 π {f}_{carrier} t ) \\ = cos ( 2 π {f}_{dev} T ) \times sin ( 2 π {f}_{carrier} t ) - sin ( 2 π {f}_{dev} T ) \times cos ( 2 π {f}_{carrier} t ) \\ = \frac{1}{2} sin ( 2 π {f}_{carrier} t + 2 π {f}_{dev} T ) + \frac{1}{2} sin ( 2 π {f}_{carrier} t - 2 π {f}_{dev} T ) - \\ \frac{1}{2} sin ( 2 π {f}_{dev} T + 2 π {f}_{carrier} t ) - \frac{1}{2} sin ( 2 π {f}_{dev} T - 2 π {f}_{carrier} t ) \\ = \frac{1}{2} sin ( 2 π {f}_{carrier} t - 2 π {f}_{dev} T ) + \frac{1}{2} sin ( 2 π {f}_{carrier} t - 2 π {f}_{dev} T ) \\ = sin ( 2 π {f}_{carrier} t - 2 π {f}_{dev} T ) \\ = sin ( 2 π {f}_{carrier} t - 2 π {f}_{dev} t + 2 π ( n - 1 ) {f}_{dev} T )\end{matrix}$$

The last term once again indicates a constant phase shift for an entire bit time period. The phase shift will be constant for any t, if f_{dev}T=integer. Thus, without imposing any limitation on the solution, it is possible to rewrite the above expression in a more general form for all D(t)=‘0’,

Y(t)=sin(2πf_{carrier}t−2πf_{dev}t)

Combining both of the above cases it can be stated that for all D(t):

Y(t)=sin(2πf_{carrier}t±2πf_{dev}t)

The above equation describes a perfect FM modulated RF signal. It is clear that this signal is independent of the input digital data, and thus, there is no degradation in FM modulation quality as a result of long ‘1’ and ‘0’ sequences that are usually present in the digital input data, especially if the digital data is being transmitted through an AC coupled interface of an ordinary, commercially available FM transmitter.

“Synthetic” Harmonic Wave Generator

The performance of the method suggested is dependent on the structure of the “synthetic” harmonic wave generator modulator. A number of potential implementations of the SHWG is possible. Two of these potential implementations are discussed in details below.

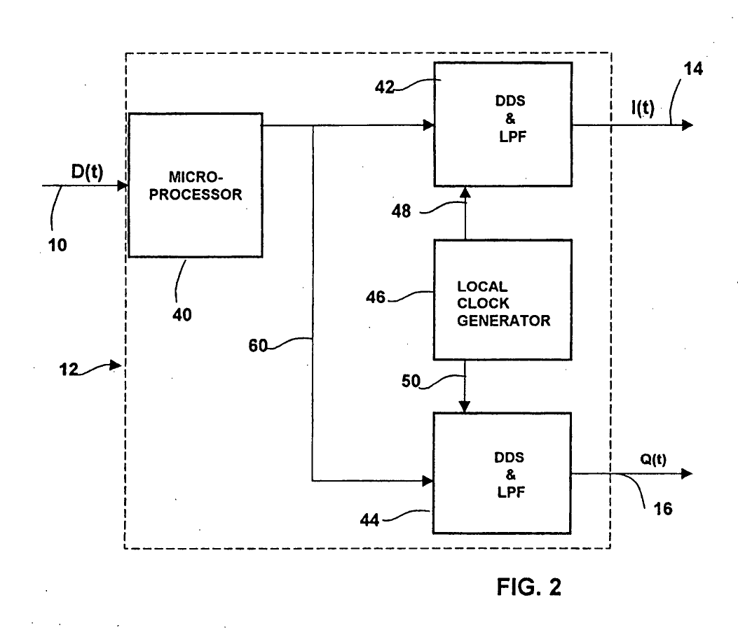

Reference is made now to FIG. 2, which is a block diagrams of one of the embodiments of a potential implementation of the “synthetic” harmonic wave generator. In accordance with this embodiment, the “synthetic” harmonic wave generator 12 comprises a microprocessor 40 with the required storage devices such as RAM, DRAM, ROM, PROM or FLASH and the support logic electronics infrastructure. Alternatively, a DSP or a micro-controller may be used instead of a microprocessor. The microprocessor receives the digital input data D(t) 10 to be transmitted and controls, through the data, address and control bus 60, two Direct Digital Synthesizer (DDS) circuits 42 and 44. The DDS circuits may be, for example, AD9850, commercially available from Analog Devices, Inc., USA The local clock generator 46 provides both DDS circuits with the necessary reference clock signals 48 and 50.

The microprocessor 40 initially programs both DDS circuits 42 and 44, enabling generation of “syrithetic” harmonic signals I(t) and Q(t), 14 and 16 respectively, of the sin(2πf_{dev}t) shape. The outputs of both DDS circuits are filtered by a Lowpass Filter (LPF), which can be constructed, for example, according to the application notes of the AD9850. At the beginning of each bit time period T, microprocessor 40 writes the new phase value to the phase control register of the DDS circuit 42. The new phase value of the signal represents the 270° phase shift of the originally programmed sin(2f_{dev}t) shape. This causes the DDS circuit 42 to begin generating signals of the form:

I(t)=sin(2πf_{dev}T+90°) for all {T=t−(n−1)T; for all t:(n−1)T≦t<nT}

or

I(t)=cos(2πf_{dev}T) for all {T=t−(n−1)T; for all t:(n−1)T≦t<nT}

Concurrently, at the beginning of each bit time period T, the microprocessor 40 writes the new phase value to the phase control register of the DDS circuit 44. The new phase value of the signal represents the 0° phase shift of the originally programmed sin(2πf_{dev}t) shape for all D(t)=D(nT)=‘1’; and also represents the 180° phase shift of the originally programmed sin(2πf_{dev}t) shape for all D(t)=D(nT)=‘0’. This causes the DDS circuit 44 to begin generating signals of the form:

Q(t)=sin(2πf_{dev}T+0°) for all {T=t−(n−1)T; for all t:(n−1)T≦t<nT}, and D(t)=‘1’;

And

Q(t)=sin(2πf_{dev}T+180°) for all {T=t−(n−1)T; for all t: (n−1)T≦t<nT}, and D(t) ‘0’.

Or

Q(t)=sin(2πf_{dev}T) for all {T=t−(n−1)T; for all t:(n−1)T≦t<nT}, and D(t)=‘1’;

And

Q(t)=−sin(2πf_{dev}T) for all {T=t−(n−1)T; for all t:(n−1)T≦t<nT}, and D(t)=‘0’.

This is the form of the signals that the “synthetic” harmonic waveform generator should produce for proper operation of the method of the present invention.

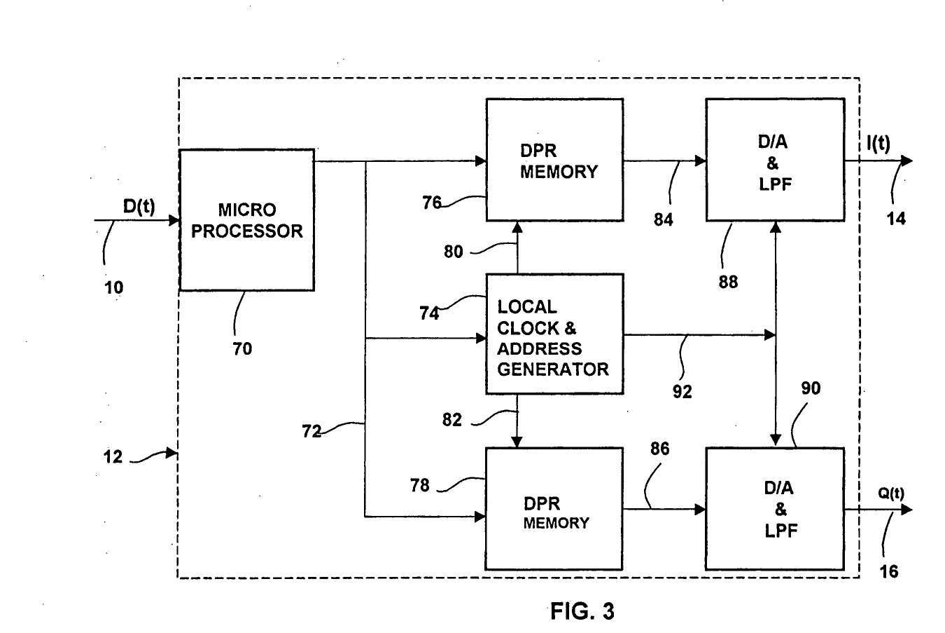

Reference is made now to FIG. 3, which is a block diagrams of another embodiment of the potential implementation of the “synthetic” harmonic wave generator. In accordance with this embodiment, the “synthetic” harmonic wave generator 12 comprises a microprocessor 70 with the required storage devices such as RAM, DRAM, ROM, PROM or FLASH and the support logic electronics infrastructure. Alternatively, a DSP or a micro-controller may be used instead of a microprocessor. Microprocessor 70 receives the digital input data D(t) 10 to be transmitted and controls, through the data, address and control bus 72, the local clock and address generator 74 and one of the interfaces of the two Dual Port RAM (DPR) memories 76 and 78.

The clock and address generator 74 controls the second interface of the two. DPR memories 76 and 78 via address and control lines 80 and 82 respectively. The data buses 84 and 86 of these interfaces are connected to the data port of the D/A circuit 88, which generates the I(t) signal 14 and the D/A circuit 90, which generates the Q(t) signal 16, respectively. The clock and address generator 74 also controls the clock signal 92 of both of the D/A circuits 88 and 90. The output of both of the D/A circuits 88 and 90 is filtered by the LPF, in order to smooth the step like output of the D/A. The LPF can be easily constructed using standard LPF implementations and well known design techniques.

The principles of the operation of this particular embodiment are given below. The microprocessor 70 initially calculates the i values of:

cos(2f_{dev}iTs) for all {i: 0≦i≦k; and kTₛ=T; and (1/f_{dev})>>Tₛ}

This series of calculated i values is scaled to fit the allowable input range of. D/A 88 and stored sequentially in the DPR 76. Following this, the microprocessor 70 calculates the i values of:

sin(2πf_{dev}iTₛ) for all {i: 0≦i≦k; and kTₛ=T; and (1/f_{dev})>>Tₛ}

and

−sin(2πf_{dev}iTₛ) for all {i: 0≦i≦k; and kTₛ=T; and (1/f_{dev})>>Tₛ}

These last two series of calculated i values are scaled to fit the allowable range of the D/A 90 and they are stored sequentially in the DPR 78. Each series is stored in a different area of the DPR 78, with a different starting address.

At the beginning of each bit time period T, the microprocessor 70, writes the starting address of the cos(2πf_{div}iTₛ) sequence in the DPR 76 to the part of the clock and address generator 74 that controls the DPR 76. In a similar manner, the starting address of sin(2πf_{dev}iTₛ) or −sin(2πf_{dev}iTₛ) sequence in the DPR 78 for D(t)=‘1’ or ‘0’ respectively, is written to the part of the clock and address generator 74 that controls the DPR 78. Starting from this moment, and during the next k periods of the sampling clock (Tₛ), which drives the clock signal of both D/A circuits 88 and 90, and the address generators in the clock and address generator 74, the address generators in the clock and address generator 74 control the DPR circuits 76 and 78, which produce at their output the relevant samples. These outputs will be converted by the D/A circuits 88 and 90 respectively into two analog signals I(t) 14 and Q(t) 16. This means that for D(t)=‘1’:

I(t)=cos(2πf_{dev}iTₛ); Q(t)=sin(2πf_{dev}iTₛ) for all {i: 0≦i≦k; and kTₛ=T; and (1/f_{dev}) >>Tₛ}

And for D(t)=‘0’:

I(t)=cos(2πf_{dev}iTₛ); Q(t)=−sin(2πf_{dev}iTₛ) for all {i: 0≦i≦k; and kTₛ=T; and (1/f_{dev})>>>Tₛ}

Once again this is the form of the signals that the “synthetic” harmonic waveform generator should produce for proper operation of the method of the present invention.

Receiver

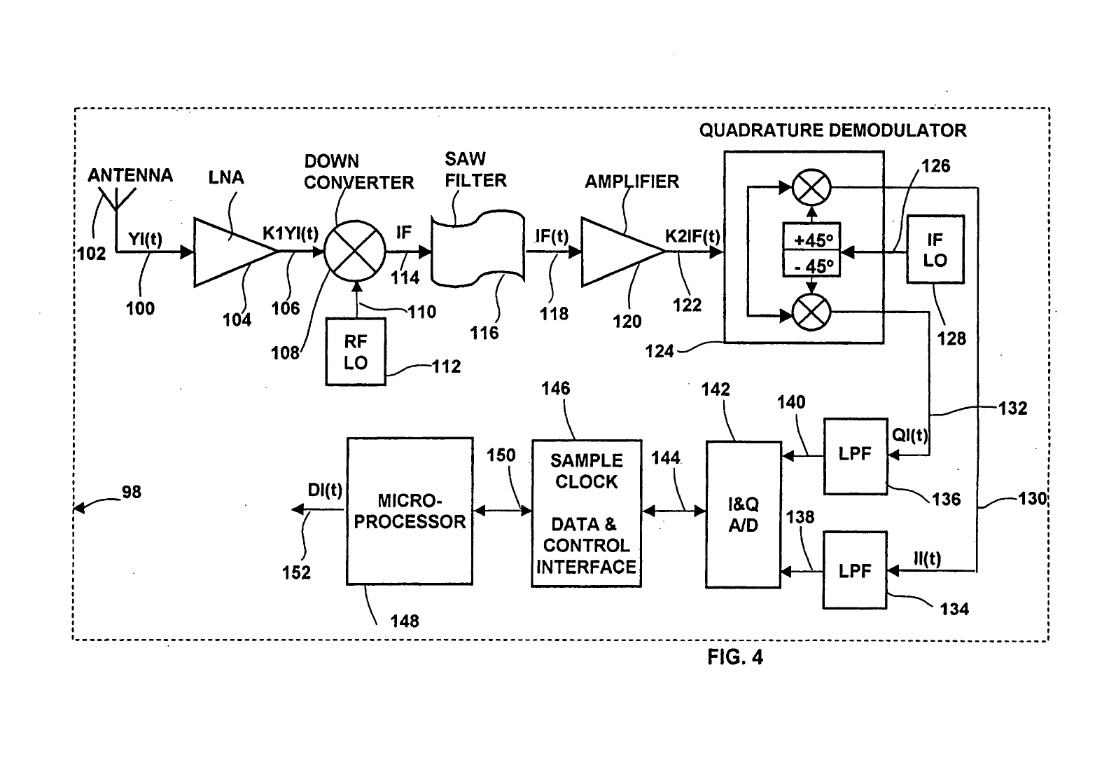

The receiver structure and operation will be explained now. FIG. 4 is a block diagram of the FM receiver 98, including the FM demodulator, constructed in accordance with the preferred embodiment of present invention. The receiver is based on the double conversion principle. This means, that the RF signal YI(t) 100 received from the antenna 102 is first amplified by a Low Noise Amplifier (LNA) 104 to produce K₁YI(t) signal 106. K₁ is the amplification coefficient of the amplifier 104. The K₁YI(t) signal is then down converted by the down converter 108, which receives its RF carrier 110 from the local RF carrier generator 112. The converted, intermediate IF signal 114 is filtered by the SAW filter 116 and produces the IF(t) signal 118. This signal is amplified by the amplifier 120 to produce the K₂IF(t) signal 122. K₂ is the amplification coefficient of the amplifier 120. The K₂IF(t) signal 122 is then demodulated by the quadrature (I-Q) demodulator 124, which receives its IF carrier 126 from the local IF carrier generator 128. The resulting II(t) 130 and QI(t) 132 signals are filtered by two LPFs 134 and 136 respectively. The outputs 138 and 140 of these two filters are sampled by the I-Q AND circuit 142, such as AD9201, commercially available from Analog Devices, Inc., USA (http//:www.analogdevices.com), or by any other suitable single or dual A/D. The sampled I-Q channels stream 144 is transferred by the sample clock, data & control interface block 146 to the microprocessor 148 through the interface 150. A DSP or micro-controller may be used instead of the microprocessor 148. The microprocessor 148 processes the I-Q samples, and generates the digital data stream DI(t) 152 based on the evaluation of the phase difference between the I and Q channels as shown below.

The receiver 98 can receive any FM modulated signal of the form:

YI(t)=A sin(2πf_{carrier}t±2πf_{dev}t)

Such that:

YI(t) A sin(2πf_{carrier}t+2πf_{dev}t); for all {(n−1)T≦t<nT}

Represents a digital data bit ‘1’, and:

YI(t)=A sin(2f_{carrier}t−2πf_{dev}t); for all {(n−1)T≦t<nT}

Represents a digital data bit ‘0’, while T is a one bit duration time.

Although the existing and commercially available systems use very precise clock generation sources, small inaccuracies between the transmitter and receiver carrier frequency generators are usually encountered. These inaccuracies in clock generation sources are more pronounced in the mobile communication systems that may be prone to frequency shifts caused by the Doppler effect. In this case, the following frequency relationships take place:

f_{carrier}=f_{RF}+f_{IF}+f_{Δ},

And, in general: |fΔ|<<f_{dev}<<f_{IF}<<f_{RF}; while: f_{carrier}≈f_{RF} Where f_{carrier} is the frequency of the RF carrier, f_{RF} is the frequency of the down converter, f_{IF} is the frequency of the quadrature (I-Q) demodulator and f_{Δ} is the frequency shift due to the Doppler effect, that for simplicity includes the clock sources difference, and remains constant during one bit time period T. The down converter function can be mathematically expressed as:

IF(t)=RF(t)×sin(2πf_{RF}t).

While the I-Q demodulator function can be mathematically expressed as:

I(t)=IF(t)×sin(2πf_{IF}t) and Q(t)=IF(t)×cos(2πf_{IF}t).

Detailed Description of the Receiver Operation

The application of the down conversion section 108 of the receiver to the RF signals K₁YI(t) 106 amplified by the LNA amplifier 104, results in the following signals at the output of the down converter 106:

For the ‘1’ signal and for all {(n−1)T≦t<nT}, the following will be the result:

AK₁ sin(2πf_{carrier}t+2πf_{dev}t)×sin(2πf_{RF}t)=

1/2AK₁ cos [t(f_{carrier}−f_{RF}+f_{dev})t]+½AK₁ cos [2π(f_{carrier}+f_{RF}+f_{dev})t]=

1/2AK₁ cos [2π(f_{IF}+f_{Δ}+f_{dev})t]+½AK₁ cos [2π(f_{carrier}+f_{RF}+f_{dev})t].

For ‘0’ signal and for all {(n−1)T≦t<nT}, the following will be the result

AK₁ sin(2πf_{carrier}−2πf_{dev})×sin(2πf_{RF}t)=

½AK₁ cos [2π(f_{carrier}−f_{RF}−f_{dev})t]+½AK₁ cos [2π(f_{carrier}+f_{RF}−f_{dev})t]=

1/2AK₁ cos [2π(f_{IF}+f_{Δ}−f_{dev})t]+½AK₁ cos[2π(f_{carrier}+f_{RF}−f_{dev})t].

The second terms will be filtered out by the Saw Filter 116 of the receiver chain and the IF(t) signal 118 will become:

For ‘1’ signal and for all {(n-1)T≦t<nT}:

IF(t)=1/2AK₁ cos [2π(F_{IF}+f_{Δ}+f_{dev})t].

For ‘0’ signal and for all {(n−1)T≦t<nT}:

IF(t)=½AK₁ cos [2π(f_{IF}+f_{Δ}f_{dev})t].

By applying to this IF(t) signal 118 additional amplifier 120 and the quadrature (I-Q) demodulator 124, it is possible to get the following II(t) 130 and QI(t) 132 signals:

For ‘1’ signal and for all {(n−1)T≦t<nT}:

II(t)=½AK₁K₂ cos [2π(f_{IF}+f_{Δ}+f_{dev})t]×sin(2πf_{IF}t)=.

½½AK₁K₂ sin [2π(2f_{IF}+f_{Δ}+f_{dev})t]+½½AK₁K₂ sin [2π(−(f_{Δ}+f_{dev}))ₜ]=

1/21/2AK₁K₂ sin [2π(2f_{IF}+f_{Δ}+f_{dev})t]−1/21/2AK₁K₂ sin [2π(f_{Δ}+f_{dev})t]=

1/21/2AK₁K₂ sin [2π(2f_{IF}+f_{Δ}+f_{dev})t]+½½AK₁K₂ cos [2π(f_{Δ}+f_{dev})t+90°].

And

QI(t)=½AK₁K₂ cos [2π(f_{IF}+fΔ+f_{dev})t]×cos(2πf_{IF}t)=.

½½AK₁K₂ cos [2π(2f_{IF}+f_{Δ}+f_{dev})t]+½½AK₁K₂ cos [2π(−(f_{Δ}+f_{dev}))t]=

1/21/2AK₁K₂ cos [2π(2f_{IF}+f_{Δ}+f_{dev})t]+½½AK₁K₂ cos [2π(f_{Δ}+f_{dev})t].

While:

For ‘0’ signal and for all {(n−1)T≦t<nT}:

II(t)=½AK₁K₂ cos [2π(f_{IF}+f_{Δ}f_{dev})t]×sin(2πf_{IF}t)=.

1/21/2AK₁K₂ sin [2π(2f_{IF}+f_{Δ}−f_{dev})t]+½½AK₁K₂ sin [2π(f_{dev}−f_{Δ})t]

1/21/2AK₁K₂ sin [2π(2f_{IF}+f_{Δ}+f_{dev})t]+½½AK₁K₂ cos [2π(f_{dev}−f_{Δ})t−90°]

And

QI(t)=½AK₁K₂ cos [2π(f_{IF}+f_{Δ}−f_{dev})t]×COS(2πf_{IF}t)=.

1/21/2AK₁K₂ cos [2π(2f_{IF}+f_{Δ}−f_{dev})t]+½½AK₁K₂ cos [2π(f_{Δ}_{-f}_{dev})t]

1/21/2AK₁K₂ cos [2π(2f_{IF}+f_{Δ}+f_{dev})t]+½½AK₁K₂ cos [2π(f_{dev}−f_{Δ})t].

Where K₁ and K₂ are the amplification coefficients of the amplifiers 104 and 120 respectively.

The first terms of the II(t) 130 and QI(t) 132 will be filtered out by the LPF circuits 134 and 136 respectively; and by substituting:

B=½½AK₁K₂;

f₁=(f_{dev}+f_{Δ});

f₀=(f_{dev}−f_{Δ});

The input signals 130 and 132 to the AID 142 will be respectively:

For ‘1’ signal and for all {(n−1)T≦t<nT}, it will be:

I channel: Bcos [2πf₁t+90°].

And

Q channel: Bcos [2πf₁t].

While:

For ‘0’ signal and for all {(n−1)T≦t<nT}, it will be:

I channel: Bcos[2πf₀t−90°].

And

Q channel: Bcos[2πf₀t].

Since, the Q signal is the same in both cases [WHY?], for ‘1’and for ‘0’, it is reasonable to base the decision of which bit is being transmitted on the evaluation of the phase shift of I signal relative to Q signal.

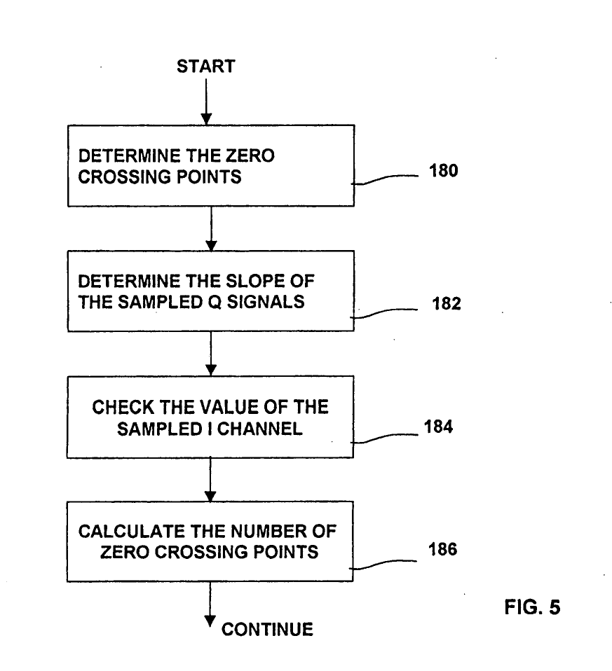

The I and Q channels 130 and 132 are sampled by the dual (or two single) A/D 142 with the sampling frequency fₛ such that: fₛ>>f_{dev}. These samples are transferred from the A/D interface 144 by the sample clock generator and data & control interface block 146 to the microprocessor 148, via the bus interface 150, for further processing. The aim of this digital processing is to determine the phase shift between the I and Q channels, in order to make a decision concerning the nature of the digital bit being transmitted and to produce a digital output data stream DI(t) 152. The algorithm of this phase evaluation-bit detection is described below, in conjunction with FIG. 5.

FIG. 5 is a flow chart of the phase evaluation-bit detection algorithm. The phase evaluation process begins at step 180, in which the algorithm determines the zero crossing points. Zero crossing points are points where slope values of the sampled Q channel signal change from positive to negative or from negative to positive.

In step 182, the algorithm determines the slope (first derivative) of the sampled Q channel signal at these zero crossing points. As the evaluation continues in step 184, the algorithm checks the value of the sampled I channel signal at these zero crossing points. If the value is positive and the slope is negative; and/or if the value is negative and the slope is positive, then a digital data ‘0’ is transmitted. If the value is positive and the slope is positive; and/or if the value is negative and the slope is negative, then a digital data ‘1’ is transmitted.

Since the ratio between the 1/f_{dev} and T (one bit time period) is known, it is possible, in step 186, to calculate the exact number of the expected zero crossing points in one bit time period and thus reproduce exactly the transmitted digital data stream.

While the invention has been particularly shown and described with reference to a preferred embodiment, it will be understood by those skilled in the art that various changes in form and detail may be made therein without departing from the spirit and scope of the invention.

What is claimed is:

1. A method for transmitting digital data using a synthetically generated frequency modulation (FM) signal, said method comprises the steps of:
receiving a digital data bit stream;
representing said digital data bit stream, on a bit by bit basis, by a first synthetically generated harmonic waveform signal of the form of cos(2πf_{dev}t) and a second synthetically generated harmonic waveform signal of the form of cos(2πf_{dev}t), wherein said first and said second waveform signal differ by a relative phase shift of ±90° as a function of the specific digital data bit;
applying said two synthetically generated signals to I and Q inputs of a quadrature (I-Q) modulator, respectively, together with a local RF oscillator frequency of f_{carrier}; and
producing a FM modulation signal of the shape sin(2πf_{carrier}t±2f_{dev}t).

2. A method for receiving digital data transmitted using a frequency modulation (FM) signal, said method comprises the steps of:
receiving a FM signal;
amplifying said FM signal;
applying down conversion from a RF carrier frequency (f_{carrier}) based on a standard downconverter (mixer) device to said amplified FM signal, wherein said amplified FM signal is of the shape sin(2πf_{carrier}t±2πf_{dev}t);
applying at least one of a SAW filter or other filter to the output of said downconverter (mixer) device in order to filter out at least one band frequency component and to receive a clean IF signal;
amplifying said IF signal;
applying said amplified IF signal to a quadrature (I-Q) demodulator together with a local frequency oscillator of f_{IF}, and producing at the I and Q outputs of said quadrature (I-Q) demodulator two harmonic signals of the shape cos(2πf_{dev}t), wherein the two harmonic signals have a relative phase shift of ±90° between the two waveforms;
applying a low pass filter to each output of said quadrature (I-Q) demodulator, in order to filter out of at least one band frequency component;
detecting a relative phase shift between said two filtered harmonic signals; and
converting said relative phase shift into a digital data output stream.

3. The method according to claim 2, wherein the step of detecting a relative phase shift between said two filtered harmonic signals further includes evaluating the sign of one channel data and the slope of a second channel data at the zero crossing points of the second channel data.

4. An apparatus for transmitting digital data using a synthetically generated frequency modulation (FM) signal, comprising:
means for receiving a digital data bit stream;
means for representing said digital data bit stream, on a bit by bit basis, by two synthetically generated harmonic waveform signals of the form of cos(2πf_{dev}t) with a relative phase shift of ±90° between the two waveforms as a function of the specific bit;
means for applying said two synthetically generated signals to I and Q inputs of the quadrature (I-Q) modulator respectively;
means for supplying a local RF oscillator frequency of f_{carrier} to said quadrature (I-Q) modulator; and
means for producing a FM modulation signal using said quadrature (I-Q) modulator, wherein said FM modulation signal is of the shape sin(2πf_{carrier}t±2πf_{dev}t).

5. The apparatus for transmitting digital data using a synthetically generated frequency modulation (FM) signal, according to claim 4, wherein said supplying means for receiving a digital data bit stream, comprises:
a microprocessor, DSP (Digital Signal Processor), or microcontroller.

6. The apparatus for transmitting digital data using a synthetically generated frequency modulation (FM) signal, according to claim 4, wherein said supplying means for representing said digital data bit stream, on a bit by bit basis, by two “synthetically” generated harmonic waveform signals of the form of cos(2πf_{dev}t) with a relative phase shift of ±90° between the two waveforms as a function of the specific digital data bit, comprises:
a first DDS (Digital Direct Synthesizer) circuit programmed on a bit by bit basis to generate a first harmonic waveform;
a second DDS circuit programmed to generate a second harmonic waveform, wherein said second harmonic waveform is phase shifted by ±90° relative to said first harmonic waveform on a bit by bit basis; and
clock generation circuitry for generating a clock signal for both DDS circuits.

7. The apparatus for transmitting digital data using a synthetically generated frequency modulation (FM) signal, according to claim 4, wherein: said supplying means for representing this digital data bit stream, on a bit by bit basis, by two “synthetically” generated harmonic waveform signals of the form of cos(2πf_{dev}t) with a relative phase shift of ±90° between the two waveforms as a function of the specific bit, comprises:
a first DPR (Dual Port RAM or other storage device) circuit storing two sets of digital samples, wherein one set of said digital samples represents the first harmonic waveform;
a second DPR (or other storage device) circuit storing two sets of digital samples, wherein one set of said digital samples represents the second harmonic waveform with a ±90° phase shift relative to the first harmonic waveform and the second set represents the second harmonic waveform with a −90° phase shift relative to the first harmonic waveform;
a first D/A (Digital to Analog) converter with a LPF, wherein said first D/A converter converts samples of the first waveform into an analog waveform;
a second D/A converter with a LPF, wherein said second D/A converter converts samples of the second waveform into an analog waveform; and
a local clock and address generator circuitry, wherein said circuitry can be programmed on a bit by bit basis to generate sequentially addresses of the first sequence in the first DPR, addresses of either first or second sequence in the second DPR and a clock signal to both D/A.

8. An apparatus for receiving digital data, wherein said digital data is transmitted using a frequency modulation (FM) signal, said apparatus comprising:
means for receiving a RF signal;
means for amplifying said RF signal using a LNA (Low Noise Amplifier);
means for down converting said RF signal to a IF signal using a downconverter (mixer) circuit, together with a local RF reference oscillator;
means for filtering said IF signal from band frequencies using a SAW filter;
means for amplifying said filtered IF signal using an amplifier;
means for demodulating said filtered IF signal into a pair of I and Q base band signals using a quadrature (I-Q) demodulator;
means for filtering said base band I signal from band frequencies using a LPF (Low Pass Filter);
means for filtering said base band Q signal from band frequencies using a LPF;
means for sampling both said I and Q base band signals using an I-Q, or dual channel or two single channel AID (Analog to Digital) converter;
means for generating an A/D sampling clock;
means for transferring said base band signals samples to a microprocessor (DSP or microcontroller) for further processing; and
means for processing said base band samples in order to detect a relative phase shift between said I and Q base band signals, and to convert said relative phase shift into a digital data output stream.

9. The apparatus for receiving digital data, which is transmitted using a frequency modulation (FM) signal, according to claim 8, wherein said supplying means for processing said base band samples in order detect a relative phase shift between said I and Q band signals, and to convert said relative phase shift into a digital data output stream, comprises:
a microprocessor, DSP (Digital Signal Processor) or microcontroller; and
a computer readable-medium executing the steps of:
determining zero crossing points (points where the change from positive to negative or from negative to positive values takes place) of first sampled base band signal;
determining the slope (first derivative) of said first sampled base band signal at said zero crossing points; and
checking at least one value of second sampled base band signal at said zero crossing points, wherein if at least one of said at least one value is positive and the slope is negative or if the value is negative and the slope is positive then a digital data ‘1’ is transmitted; and if at least one of said at least one value is positive and the slope is positive or negative and the slope is negative then a digital data ‘0’ is transmitted.
